(19) United States
(12) Patent Application Publication
(10) Pub. No.: US 2013/0343812 A1
(43) Pub. Date: Dec. 26, 2013

(54) SHEET METAL PART FOR LCD DEVICE, LCD DEVICE, AND METHOD FOR MANUFACTURING SHEET METAL PART

(71) Applicants: Lifeng Wang, Shenzhen (CN); Yajun Yu, Shenzhen (CN); Yanxue Zhang, Shenzhen (CN)

(72) Inventors: Lifeng Wang, Shenzhen (CN); Yajun Yu, Shenzhen (CN); Yanxue Zhang, Shenzhen (CN)

(21) Appl. No.: 13/577,739

(22) PCT Filed: Jun. 26, 2012
(86) PCT No.: PCT/CN12/77494

§ 371 Date: Aug. 8, 2012

(30) Foreign Application Priority Data
Jun. 21, 2012 (CN) 201210207863.7

(51) Int. Cl. H05K 5/02; B21D 43/28

(52) U.S. Cl. 403/343; 72/324

(57) ABSTRACT

The present disclosure relates to the field of liquid crystal displays (LCDs), and more particularly to a sheet metal part for an LCD device, an LCD device, and a method for manufacturing a sheet metal part for an LCD device. The sheet metal part comprises an inner hole flange, the flange comprises an internal thread, and a circumference of a cross section of the inner hole comprises at least one protrusion protruding to a direction of a center of circle of cross section of the inner hole. The sheet metal part for the LCD device of the present disclosure comprises the inner hole flange. The flange comprises the internal thread, and the circumference of the cross section of the inner hole comprises at least one protrusion protruding to the direction of the center of circle of cross section of the inner hole. The protrusion changes a shape of the inner hole, so that the inner hole is not a complete circular hole any more. After tapping the standard internal thread on the flange, the thread tooth of the protrusion is deep, thereby bearing much torsion; the thread teeth of other parts are shallow, the thread wall is thick; thus, the strength of the inner hole is increased, thereby improving the locking reliability of the thread of the inner hole on the whole.

### TECHNICAL FIELD

The present disclosure relates to the field of liquid crystal displays (LCDs), and more particularly to a sheet metal part for an LCD device, an LCD device, and a method for manufacturing a sheet metal part.

### BACKGROUND

A typical liquid crystal display (LCD) device includes a backlight module. The backlight module specifically includes a front frame, a middle frame, a backplane, a light source, a light guide panel, and an LCD panel. Both the front frame and the backplane can be formed by stamping thin sheet metal parts. To connect these sheet metal parts with other components, each sheet metal part is configured with a screw hole. To increase the length of fitting with a screw, as shown in FIG. 1 and FIG. 2, the sheet metal part is generally configured with an inner hole flange 1, and the inner hole 2 with the flange 1 is configured with an internal thread 3. To reduce the cost, the sheet metal part is thinner and thinner, and the wall of the screw hole is thinner and thinner, thereby resulting in the strength reduction of the screw hole. The torsion which the screw hole bears is smaller and smaller, which results in the reliability reduction of locking Take a screw hole of M4 as an example, under the conditions of the same length of the thread fit and the same depth of the thread tooth, the screw hole can bear the torsion of 18 kgf when using a sheet metal part made of steel electrodeposition cold common (SECC) material (electro-galvanized steel sheet) with the thickness of 0.8 mm, and the screw hole can only bear the torsion of 9 kgf when using the sheet metal part made of SECC material with the thickness of 0.6 mm. Thus, the torsion requirement is not achieved, and further affecting thinning the sheet metal part.

### SUMMARY

In view of the above-described problems, the aim of the present disclosure is to provide a sheet metal part for a liquid crystal display (LCD) device, an LCD device, and a method for manufacturing a sheet metal part. The strength of a screw hole in the sheet metal part is high, and the torsion which the screw hole bears is great.

A first technical scheme of the present disclosure is that: a sheet metal part for an LCD device is configured with an inner hole flange, the flange is configured with an internal thread, and a circumference of a cross section of the inner hole is configured with at least one protrusion protruding to a direction of a center of circle of cross section of the inner hole.

In one example, a contour line of the protrusion is an inner arc line, an outer arc line, or a straight line.

In one example, the circumference of the cross section of the inner hole is configured with a plurality of protrusions, and these protrusions are uniformly arranged on the circumference of the inner hole. By uniformly arranging these protrusions, a wall thickness of a screw hole can be in a regular state, and the torsion which the screw hole bears is stable.

In one example, the circumference of the cross section of the inner hole is configured with two protrusions, and the two protrusions are arranged every 180°.

In one example, the circumference of the cross section of the inner hole is configured with three protrusions, and the three protrusions are arranged every 120°.

In one example, the circumference of the cross section of the inner hole is configured with two protrusions; the contour line of each protrusion is in a half oval shape, and the contour lines of the two protrusions form a complete oval.

In one example, the sheet metal part is a backplane.

The present disclosure further provides a method for manufacturing a sheet metal part for an LCD device, which comprises the following steps:

Stamping a small hole in the sheet metal part in advance, a circumference of the small hole is configured with at least one protrusion protruding to a direction of a center of circle of cross section of the small hole;

Performing an inner hole flange around the small hole, a circumference of a cross section of the inner hole with the flange is configured with at least one protrusion protruding to the direction of the center of circle of cross section of the inner hole; and

Tapping an internal thread on the flange.

In one example, before the step of stamping the small hole in the sheet metal part in advance, the method further comprises a step: stamping a hillock on the sheet metal part, after that, planishing a top of the hillock. The top of the hillock is used for forming the small hole and the inner hole flange.

The method has the advantages that no process is added, no new technology is introduced, and only different punches of a stamping die are replaced on the basis of a typical stamping mode, namely an original punch of cylindrical is replaced by a punch with an internal concave.

The present disclosure further provides a second technical scheme: an LCD device comprises the sheet metal part mentioned above.

Advantages of the present disclosure are summarized below: the sheet metal part for the LCD device of the present disclosure comprises the inner hole flange, the flange is configured with the internal thread, and the circumference of the cross section of the inner hole is configured with at least one protrusion protruding to the direction of the center of circle of cross section of the inner hole. The protrusion changes the shape of the inner hole, so that the inner hole is not a complete circular hole any more. After tapping the standard internal thread on the flange, the thread tooth of the protrusion is deep, thereby bearing much torsion; the thread teeth of other parts are shallow, the thread wall is thick; thus, the strength of the inner hole is increased, thereby improving the locking reliability of the screw hole on the whole.

### BRIEF DESCRIPTION OF FIGURES

FIG. 1 is a schematic diagram of an inner hole flange of a typical sheet metal part for an LCD device;

FIG. 2 is a cutaway view of A-A shown in FIG. 1;

FIG. 3 is a schematic diagram of an inner hole flange of a sheet metal part for an LCD device of a first example of the present disclosure;

FIG. 4 is a cutaway view of B-B shown in FIG. 3;

FIG. 5 is a cutaway view of C-C shown in FIG. 3;

FIG. 6 is a schematic diagram of an inner hole flange of a sheet metal part for an LCD device of a second example of the present disclosure;

FIG. 7 is a schematic diagram of an inner hole flange of a sheet metal part for an LCD device of a third example of the present disclosure; and

FIG. 8 is a schematic diagram of an inner hole flange of a sheet metal part for an LCD device of a fourth example of the present disclosure.

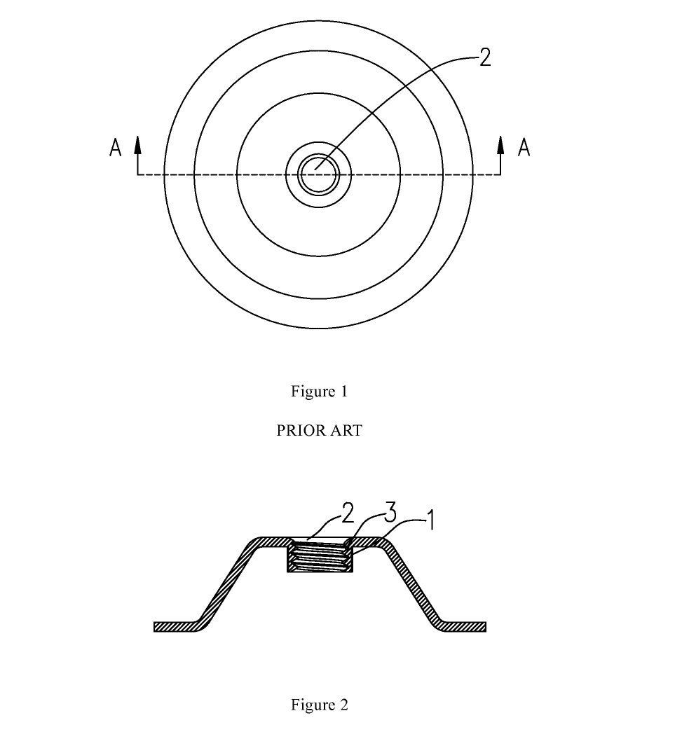

Legends: 1. flange; 2. inner hole; 3. internal thread; 4. protrusion.

### DETAILED DESCRIPTION

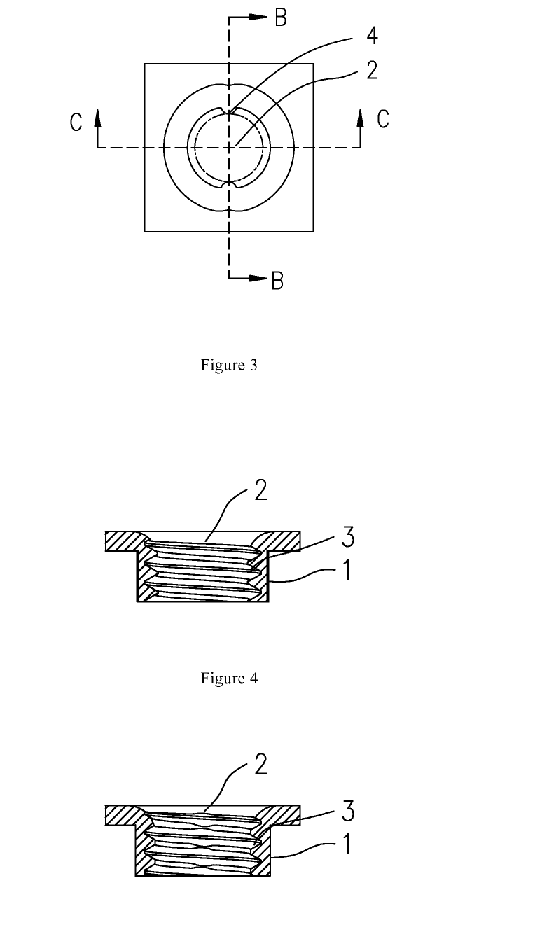

The present disclosure provides a liquid crystal display (LCD) device, the LCD device comprises a sheet metal part. FIGS. 3-5 show a first example of the sheet metal part for the LCD device. The sheet metal part is configured with an inner hole flange 1, the flange 1 is configured with an internal thread 3, and a circumference of a cross section of the inner hole 2 is configured with at least one protrusion 4 protruding to a direction of a center of circle of cross section of the inner hole. In the example, the circumference of the cross section of the inner hole 2 is configured with two protrusions 4, and the two protrusions 4 are arranged every 180°.

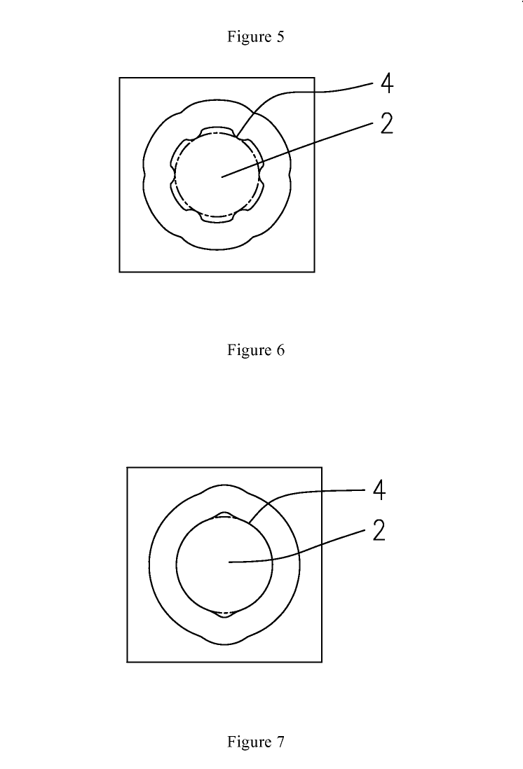

The sheet metal part for the LCD device of the present disclosure comprises the inner hole flange 1, the flange 1 is configured with the internal thread 3, and the circumference of the cross section of the inner hole 2 is configured with at least one protrusion 4 protruding to the direction of the center of circle of cross section of the inner hole. The protrusion 4 changes a shape of the inner hole 2, so that the inner hole 2 is not a complete circular hole any more. After tapping the standard internal thread 3 on the flange 1, as shown in FIG. 4, the thread tooth of the protrusion is deep, thereby bearing much torsion. As shown in FIG. 5, the thread teeth of other parts are shallow, the thread wall is thick. Thus, the strength of the inner hole 2 is increased, thereby improving the entire locking reliability of a screw hole.

For a typical sheet metal part for the LCD device, by taking a backplane as an example, a thickness of the thinnest backplane is 0.6 mm. For the backplane using the sheet metal part of the present disclosure, the screw hole can bear the same torsion when a thickness of the sheet metal part is 0.5 mm, thereby significantly reducing the material cost. Optionally, the sheet metal part can be a front frame.

The present disclosure further provides a method for manufacturing a sheet metal part for an LCD device, which comprises the following steps:

Stamping a small hole in the sheet metal part in advance, a circumference of the small hole is configured with at least one protrusion protruding to a direction of a center of circle of cross section of the small hole;

Performing an inner hole flange around the small hole, a circumference of a cross section of the inner hole with the flange is configured with at least one protrusion protruding to the direction of the center of circle of cross section of the inner hole; and

Tapping an internal thread on the flange.

The aforementioned sheet metal part can be manufactured by using the method for manufacturing the sheet metal part for the LCD device of the present disclosure, and the aforementioned advantages can be achieved. The method has the advantages that no process is added, no new technology is introduced, and only different punches of a stamping die are replaced on the basis of a typical stamping mode, namely an original punch of cylindrical is replaced by a punch with an inner concave.

The task of stamping the small hole in the sheet metal part in advance and performing the inner hole flange around the small hole can be completed in one stamping process by a set of stamping die when the punch of the die has a step structure.

To prevent the flange of the sheet metal part from mutually interfering with an internal structure of the LCD device, before the step of stamping the small hole in the sheet metal part in advance, the method further comprises a step: stamping a hillock on the sheet metal part, after that, planishing a top of the hillock. The top of the hillock is used for forming the small hole and the inner hole flange. The flange formed by the method is lower than a plane of the sheet metal part, and does not mutually interfere with the internal structure of the LCD device.

In the first example of the sheet metal part for the LCD device, a contour line of the protrusion 4 is an outer arc line. Optionally, the contour line can be a straight line or an inner arc line.

In the first example of the sheet metal part for the LCD device, the circumference of the cross section of the inner hole 2 is configured with two protrusions 4, and the two protrusions 4 are arranged every 180°. Optionally, the circumference of the cross section of the inner hole is configured with a plurality of protrusions, and these protrusions are uniformly arranged on the circumference of the inner hole. By uniformly arranging these protrusions, a wall thickness of the screw hole can be in a regular state, and the torsion which the screw hole bears is stable. For example, the circumference of the cross section of the inner hole is configured with three protrusions, and the three protrusions are arranged every 120°. Or as shown in FIG. 6, in a second example of the sheet metal part for the LCD device, the circumference of the cross section of the inner hole 2 is configured with six protrusions 4, and the six protrusions are arranged every 60°.

FIG. 7 shows a third example of the sheet metal part for the LCD device. The circumference of the cross section of the inner hole 2 is configured with two protrusions 4; the protrusion 4 is long, and the contour line of each protrusion 4 is an inner arc line, thereby obtaining the same advantages as those in the first example.

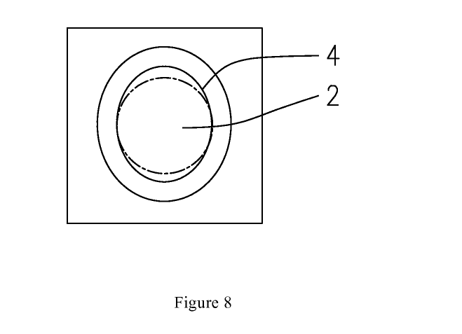

FIG. 8 shows a fourth example of the sheet metal part for the LCD device of the present disclosure. The circumference of the cross section of the inner hole 2 is configured with two protrusions 4; the contour line of each protrusion 4 is in a half oval shape, and the contour lines of the two protrusions 4 form a complete oval, thereby obtaining the same advantages as those in the first example.

The present disclosure is described in detail in accordance with the above contents with the specific exemplary examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

We claim:

1. A sheet metal part for a liquid crystal display (LCD) device, comprising
an inner hole flange, wherein the flange comprises an internal thread, and a circumference of a cross section of the inner hole comprises at least one protrusion protruding to a direction of a center of circle of cross section of the inner hole.

2. The sheet metal part for the LCD device of claim 1, wherein a contour line of the protrusion is an inner arc line, an outer arc line, or a straight line.

3. The sheet metal part for the LCD device of claim 1, wherein the circumference of the cross section of the inner hole comprises a plurality of protrusions, and the plurality of protrusions are uniformly arranged on the circumference of the inner hole.

4. The sheet metal part for the LCD device of claim 3, wherein the circumference of the cross section of the inner hole comprises two protrusions, and the two protrusions are arranged every 180°.

5. The sheet metal part for the LCD device of claim 3, wherein the circumference of the cross section of the inner hole comprises three protrusions, and the three protrusions are arranged every 120°.

6. The sheet metal part for the LCD device of claim 2, wherein the circumference of the cross section of the inner hole comprises two protrusions; the contour line of each protrusion is in a half oval shape, and the contour lines of the two protrusions form a complete oval.

7. The sheet metal part for the LCD device of claim 3, wherein the sheet metal part is a backplane.

8. A method for manufacturing a sheet metal part for a liquid crystal display (LCD) device, comprising:
Stamping a small hole in the sheet metal part in advance; a circumference of the small hole comprises at least one protrusion protruding to a direction of a center of circle of cross section of the small hole;
Performing an inner hole flange around the small hole; a circumference of a cross section the inner hole with the flange comprises at least one protrusion protruding to a direction of a center of circle of cross section of the inner hole; and
Tapping an internal thread on the flange.

9. The method for manufacturing the sheet metal part for the LCD device of claim 8, wherein before the step of stamping the small hole in the sheet metal part in advance, the method further comprises a step: stamping a hillock on the sheet metal part, after that, planishing a top of the hillock; the top of the hillock is used for forming the small hole and the inner hole flange.

10. A liquid crystal display (LCD) device, comprising:
a sheet metal part, comprising an inner hole flange;
wherein the flange comprises an internal thread, and a circumference of a cross section of the inner hole comprises at least one protrusion protruding to a direction of a center of circle of cross section of the inner hole.

11. The LCD device of claim 10, wherein a contour line of the protrusion is an inner arc line, an outer arc line, or a straight line.

12. The LCD device of claim 10, wherein the circumference of the cross section of the inner hole comprises a plurality of protrusions, and the plurality of protrusions are uniformly arranged on the circumference of the inner hole.

13. The LCD device of claim 12, wherein the circumference of the cross section of the inner hole comprises two protrusions, and the two protrusions are arranged every 180°.

14. The LCD device of claim 12, wherein the circumference of the cross section of the inner hole comprises three protrusions, and the three protrusions are arranged every 120°.

15. The LCD device of claim 11, wherein the circumference of the cross section of the inner hole comprises two protrusions; the contour line of each protrusion is in a half oval shape, and the contour lines of the two protrusions form a complete oval.

16. The LCD device of claim 12, wherein the sheet metal part is a backplane.
